(19) United States
(12) Patent Application Publication
(10) Pub. No.: US 2006/0113567 A1
(43) Pub. Date: Jun. 1, 2006

(54) Semiconductor integrated circuit and method of producing same

(75) Inventors: Mutsuhiro Ohmori, Kanagawa (JP); Tomofumi Arakawa, Tokyo (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 11/248,289

(22) Filed: Oct. 13, 2005

(30) Foreign Application Priority Data
Oct. 14, 2004 (JP) P2004-300014

(51) Int. Cl. H01L 27/10

(52) U.S. Cl. 257/202

(57) ABSTRACT

A semiconductor integrated circuit able to repair a defect of a circuit cell without greatly changing interconnects, that is, a semiconductor integrated circuit comprising a plurality of circuit cells aligned in a matrix and groups of interconnects connecting at least a part of the plurality of circuit cells other than one or more lines of unused circuit cells aligned in a row direction or a column direction.

### CROSS REFERENCES TO RELATED APPLICATIONS

The present invention contains subject matter related to Japanese Patent Application No. 2004-300014 filed in the Japan Patent Office on Oct. 14, 2004, the entire contents of which being incorporated herein by reference.

### BACKGROUND OF THE INVENTION

1. Field of Invention

The present invention relates to for example a structured ASIC or other semiconductor integrated circuit having a plurality of circuit cells forming basic configuration units connected to form a circuit and a method of producing the same, more particularly relates to a semiconductor integrated circuit reducing the drop in yield due to defects of the circuit cells and a method of producing the same.

2. Description of the Related Art

A structured ASIC is an IC using circuit cells each having a structure smaller in size than even a basic gate such as a NAND circuit as the smallest configuration units of the circuit.

As a representative publication concerning the basic logic configuration units of a structured ASIC, there is for example “Regular logic fabrics for a via patterned gate array (VPGA), CMU K. Y. Tong, IBM R. Puri, IEEE 2003 Custom integrated circuits conference”. In this publication, the basic configuration unit is configured by a three-input lookup table, a scan flip-flop, two three-input NAND circuits, and seven buffers.

In a structured ASIC, unlike a field programmable gate array (FPGA), circuits having desired functions are configured by a mask route for customizing part of the interconnects in accordance with the application. The reconfigurable interconnect structure in a FPGA has very large waste, but by replacing the interconnect structure by mask route, while there is greater waste than the standard cell system, it is possible to develop a circuit with much less waste than a FPGA in a short period.

On the other hand, in recent semiconductor integrated circuits, there have been great strides in miniaturization of processing dimensions and enlargement of the scale of circuit. The reduction of the yield due to defects has therefore become serious.

For example, in the method of generation of dat of a logic circuit of an FPGA disclosed in Japanese Patent No. 3491579, the necessity for avoiding malfunctions is judged from malfunction information and logic information and, if necessary, the logic information is changed so as to replace a function of a malfunction portion by an empty portion.

### SUMMARY OF THE INVENTION

In a structured ASIC, however, the final customized interconnects have not yet been completed at the stage of testing for the defects, therefore it is not possible to use the technique of provisionally laying interconnects for the test and changing the interconnects for actual use as in a FPGA. Accordingly, the method of overcoming defects in a FPGA as shown in Japanese Patent No. 3491579 cannot be used for a structured ASIC.

Further, in the method of Japanese Patent No. 3491579, since the interconnects are changed so as to repair individual defects of basic cells, it suffers from the disadvantage that circuits for changing the interconnects increase and the cost becomes higher. Further, it suffers from the disadvantage that the delay characteristic may be become remarkably worse due to the large change in the interconnects for repairing defects. If making the design delay margin too large by estimating the deterioration of the delay characteristic, it becomes hard to raise the performance of the operation speed.

There is a need for providing a semiconductor integrated circuit able to repair the defects of circuit cells without greatly changing the interconnects and a method of producing the same.

According to the present invention, there is provided a semiconductor integrated circuit including a plurality of circuit cells aligned in a row direction and a column direction in a matrix form and including at least one line of unused ciruit cells aligned in the row direction or the column direction and a plurality of usable circuit cells, and at least one group of interconnects connecting at least a part of the pulurality of usable circuit cells.

Preferably, the plurality of circuit cells are divided into a plurality of blocks each including one or more lines of unused circuit cells aligned in the row direction or the column direction, and the groups of interconnects connect at least a part of the plurality of usable circuit cells in each of the blocks.

Preferably, the line of unused circuit cells include a defective circuit cell.

Preferably, The groups of interconnects include a first group of interconnects including an input interconnect and an output interconnect of each circuit cell, a second group of interconnects, and a third group of interconnects including an interconnect selectively connecting an interconnect included in the first group of interconnects and an interconnect included in the second group of interconnects and an interconnect selectively connecting interconnects included in the second group of interconnects to each other.

Preferably, the first group of interconnects is formed in a first interconnect layer, the second group of interconnects is formed in a second interconnect layer covering the first interconnect layer, and the third group of interconnects includes a via selectively connecting an interconnect formed in the first interconnect layer and an interconnect formed in the second interconnect layer.

Preferably, the second group of interconnects include a group of interconnects extending in the row direction and formed in the first interconnect layer, a group of interconnects extending in the column direction and formed in the second interconnect layer, a group of interconnects connecting the interconnects extending in the row direction to each other through the via and formed in the second interconnect layer, and a group of interconnects connecting the interconnects extending in the column direction to each other through the via and formed in the first interconnect layer.

Preferably, the plurality of circuit cells can be programmed in logic functions.

Preferably, each circuit cell includes one or more first nodes, one or more second nodes, and interconnects selectively connecting the first node and the second node. In this case, each circuit cell may have a logic function in accordance with the state of connection of the first nodes and the second nodes.

Preferably, each circuit cell includes one or more first nodes connected to an interconnect formed in the first interconnect layer, one or more second nodes connected to an interconnect formed in the second interconnect layer, and one or more vias selectively connecting the first nodes and the second nodes. In this case, each circuit cell may have a logic function in accordance with the state of connection of the first nodes and the second nodes.

Preferably, the semiconductor integrated circuit further includes a power supply control circuit for controlling whether or not the power is supplied for each line of circuit cells aligned in the same direction as the direction in which the unused circuit cells are aligned and at least cutting off the supply of the power to the unused circuit cells.

Preferably, the semiconductor integrated circuit comprises at least one power supply line and a plurality of branch lines branching from said power supply line to said blocks and supplying power to each line of circuit cells aligned in the same direction as the direction of alignment of unused circuit cells in the blocks. In this case, the power supply control circuit may include a plurality of fuse circuits inserted between said power supply line and plurality of branch lines.

Preferably, the semiconductor integrated circuit comprises a plurality of test output lines connected to circuit cells in the same row, a plurality of column selection lines connected to circuit cells in the same column, a column selecting circuit for successively activating the plurality of column selection lines in an operation mode for testing the circuit cells, and a test signal input circuit for inputting test signals to the plurality of circuit cells in the operation mode for testing the circuit cells. In this case, each circuit cell may generate a signal in accordance with an input test signal when the connected column selection line is activated in the operation mode for testing the circuit cell and may output the generated signal to the connected test output line.

According to the present invention, there is also provided a method of producing a semiconductor integrated circuit comprising a first step of forming a plurality of circuit cells aligned in a row direction and a column direction in a matrix form, a second step of testing each of the plurality of circuit cells, a third step of determining a first interconnect route, when all of the plurality of circuit cells are judged to be normal in the second step, so that one or more lines of predetermined circuit cells aligned in the row direction or the column direction among the plurality of circuit cells are unused and at least a part of the plurarity of circuit cells other than the unused circuit cells are in use, a fourth step of determining a second interconnect route, when a defective circuit cell is found among the plurality of circuit cells in the test of the second step, so that the line of circuit cells including the defective circuit cell and aligning in the same direction as the direction in which the predetermined circuit cells are aligned are unused in place of at least part of the lines of the predetermined circuit cells and at least a part of the plurarity of the circuit cells other than the unused circuit cells are in use, and a fifth step of forming a group of interconnects connecting at least a part of the plurarity of circuit cells other than the unused circuit cells based on the first interconnect route or the second interconnect route.

Preferably, each of the divided blocks of said plurality of circuit cells are tested in the second step, the first interconnect route for a block judged to be normal by the second step are determined in the third step, and the second interconnect route for a block judged to include a defective circuit cell by the second step are determined in the forth step.

Preferably, circuit cells able to be programmed in logic function are formed in the first step, the logic functions of at least part of the plurarity of circuit cells other than the unused circuit cells are determined in the third step and the forth step, and the logic functions of at least part of the plurarity of circuit cells other than the unused circuit cells based on the determined logic functions are programmed in the fifth step.

Preferably, a power supply control circuit for controlling whether or not power is supplied for each line of circuit cells aligned in the same direction as the direction in which the unused circuit cells are aligned in each of the blocks and supplying power to all lines of circuit cells is formed in the first step, and the power supply control circuit is programmed so that the supply of the power to at least the line in which the defective circuit cell is found in the second step is cut off in the fifth step.

According to the present invention, by previously setting as unused one or more lines of circuit cells aligned in the row direction or the column direction among a plurality of circuit cells aligned in the matrix, a defect of the circuit cell can be repaired without greatly changing the interconnect patterns.

### BRIEF DESCRIPTION OF THE DRAWINGS

These and other objects and features of the present invention will become clearer from the following description of the preferred embodiments given with reference to the attached drawings, wherein:

FIG. 1 is a diagram of an example of the configuration of a semiconductor integrated circuit according to an embodiment of the present invention;

FIG. 2 is a diagram of an example of the configuration of a block;

FIG. 3, consisting of FIG. 3A and FIG. 3B, is a diagram for explaining a method of repairing a defect of a circuit cell in the semiconductor integrated circuit shown in FIG. 1;

FIG. 4 is a diagram of an example of the configuration of a circuit cell of a semiconductor integrated circuit according to an embodiment having a structured ASIC configuration;

FIG. 5 is a diagram of an example of an interconnect structure of a semiconductor integrated circuit according to an embodiment having the circuit cell shown in FIG. 4;

FIG. 6 is a diagram of an example of an interconnect pattern in the interconnect structure shown in FIG. 5;

FIG. 7 is a first diagram of an example of a change of the interconnect patterns along with repair of a defect;

FIG. 8 is a second diagram of an example of a change of the interconnect patterns along with repair of a defect;

FIG. 9 is a diagram of an example of a circuit according to test of circuit cells;

FIG. 10 is a flow chart illustrating an example of test processing by the circuit shown in FIG. 9;

FIG. 11 is a diagram showing an example of a circuit for controlling a supply of power with respect to circuit cells; and

FIG. 12 is a flow chart illustrating an example of a method of producing the semiconductor integrated circuit according to an embodiment.

### DESCRIPTION OF THE PREFERRED EMBODIMENTS

Below, an explanation will be given of an embodiment of the present invention by referring to the drawings.

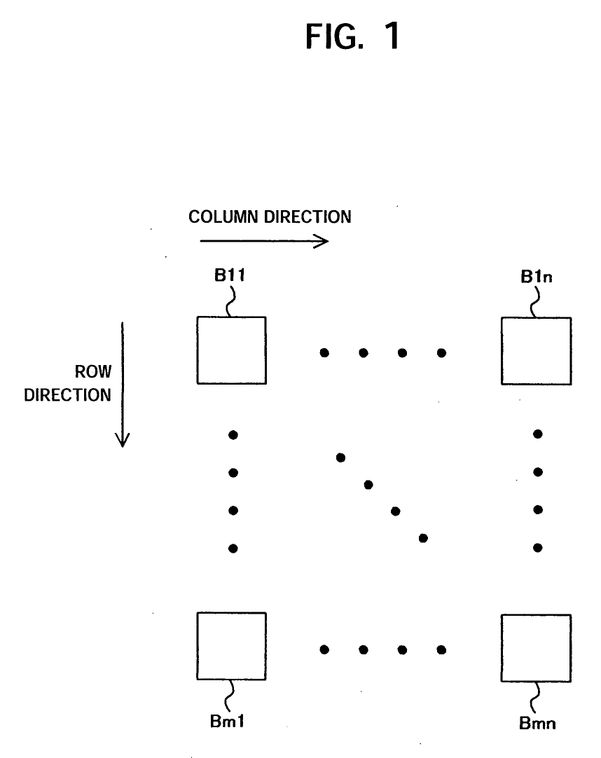

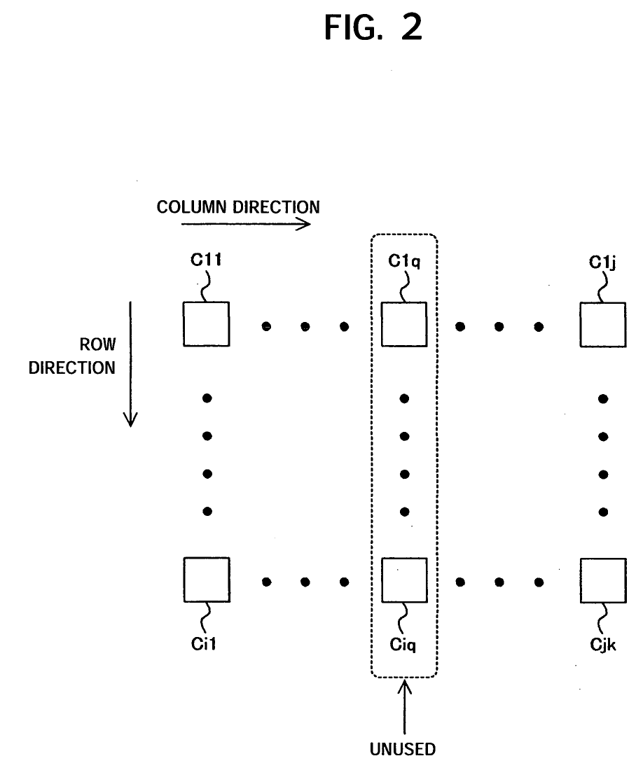

FIG. 1 is a diagram of an example of the configuration of a semiconductor integrated circuit according to an embodiment of the present invention. The semiconductor integrated circuit shown in FIG. 1 has blocks B11 to Bmn of circuit cells aligned in a matrix consisting of n rows and m columns. Each block, as shown in FIG. 2, includes circuit cells Cll to Cjk aligned in a matrix consisting of j rows and k columns. Accordingly, the semiconductor integrated circuit shown in FIG. 1 has a plurality of (m×n×j×k) circuit cells aligned in a matrix. These circuit cells are divided into a plurality of (m×n) blocks.

The circuit cells Cll to Cjk may be basic cells having a fixed logic function as in for example a NAND circuit or may be circuits able to be programmed with a logic function as will be explained later.

The circuit cells Cll to Cjk are connected in a not shown interconnect layer to form a circuit having a specific function. Note that the circuit cells Clq to Ciq in the q-th columns (1≦q≦j) were treated as cells of unused columns previously. When there is no defect in other circuit cells, the circuit cells Clq to Ciq in the q-th columns are not connected to the other circuit cells in the interconnect layer.

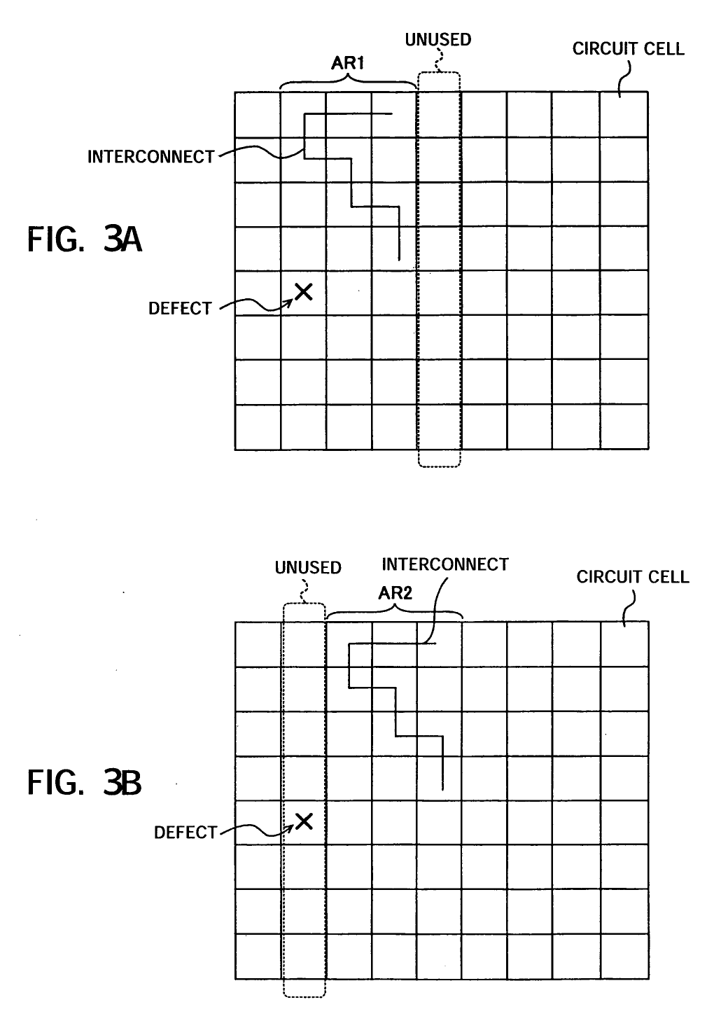

FIG. 3 is a diagram for explaining a method for repairing a defect of a circuit cell in the semiconductor integrated circuit shown in FIG. 1. In the semiconductor integrated circuit shown in FIG. 1, for example, at a stage after forming the circuit cells on the semiconductor substrate, each circuit cell is tested. When the result of test is that no defect of a circuit cell is found, interconnects connecting part or all of the remainder of circuit cells other than the circuit cells in the q-th columns are formed based on the interconnect route designed setting as unused the q-th columns. Further, when using a circuit cell able to be programmed in logic function, the logic function of each circuit cell is programmed based on the arrangement of the circuit cells designed setting as unused the q-th columns.

On the other hand, when the result of the test of circuit cells is that, for example as shown in FIG. 3A, a circuit cell having a defect (hereinafter referred to as a defective cell) is found in a certain block, the column including the defective cell is selected as the unused column in place of a q-th column unused in the initial setup. Namely, when the column including the defective cell is set as unused, the interconnect route of the circuit cells is redesigned. Then, based on the redesigned new interconnect route, interconnects connecting at least a part of the remainder of circuit cells other than the column including the defective cell are formed. When using circuit cells able to be programmed in logic function, the arrangement of circuit cells is redesigned by setting as unused the column including the defective cell, and the logic function of each circuit cell is programmed based on this redesigned new cell arrangement.

The change of an unused line from a certain column to another column means movement of the unused line in the row direction in parallel. As shown in FIG. 3B, when moving the unused line in the row direction in parallel, the change of the interconnect patterns can be accomplished by parallel movement of the interconnect patterns in a certain region to another region. Namely, the interconnect patterns corresponding to a region AR1 from a line in which a defective cell was found to an unused line in the initial setup may be shifted to a region AR2 offset from it by one line's worth toward the unused line in the initial setup. Accordingly, by a very easy change of interconnect patterns, a circuit having an equivalent function can be configured. Further, when the logic function of each circuit cell can be programmed, along with the shift of the interconnect patterns explained above, the logic function of each circuit cell may be shifted from the region AR1 to the region AR2. For this reason, even in the case where circuit cells having unique logic functions are provided, the change of arrangement of circuit cells is very easy.

As explained above, according the semiconductor integrated circuit of the present embodiment, among the plurality of circuit cells aligned in the matrix, one or more lines of circuit cells aligned in the column direction are not interconnected and are left unused. Therefore, by setting as unused a line in which a defective cell is found in place of a line set as unused in the initial setup, the defect of the semiconductor integrated circuit is repaired and therefore the yield can be greatly improved. Further, in this case, the functions of circuit cells used in the region between a line set as unused in the initial setup and a line in which the defective cell is found are shifted overall and the interconnect patterns are shifted overall in accordance with this. Therefore, the change of the interconnect patterns and arrangement along with repair of a defect can be greatly reduced.

If defects of the circuit cells were not repaired in unit of columns, but were repaired for individual circuit cells, the change of the interconnect patterns necessary when replacing a defective cell by a normal circuit cell would become very complex. For this reason, in order to determine the interconnect route in real time while testing each circuit cell in for example a production line of a factory, it would necessary to perform the computation at a high speed by using a very high performance computer, so there are disadvantages such as a rise of costs and a drop of production efficiency. According to the semiconductor integrated circuit of the present embodiment, the very simple processing of shifting the logic functions and interconnect patterns of the circuit cells in a certain region to another region enables the change of the interconnect patterns and the change of the arrangement of circuit cells along with the retpair of a defect, therefore there is almost none of the above disadvantage.

Further, according to the semiconductor integrated circuit of the present embodiment, one or more lines of unused circuit cells are provided for each block, therefore defects can be repaired in unit of blocks. If repairing the defects not in units of blocks, but by the semiconductor integrated circuit as a whole there would be the disadvantage that defects present scattered around a semiconductor chip would not be able to be efficiently repaired. For example, if providing only one line of unused circuit cells in the entire semiconductor integrated circuit, only defects included in one line could be repaired in the semiconductor integrated circuit. If the defects were scattered over two or more lines, all of the defects could no longer be repaired and therefore the entire semiconductor integrated circuit would become a defective product. Contrary to this, if repairing defects in units of blocks as in the present embodiment, at least one defect can be repaired in each block, therefore defects scattered around the semiconductor chip can be efficiently repaired.

Next, an explanation will be given of an example of applying the semiconductor integrated circuit according to the present embodiment to a structured ASIC.

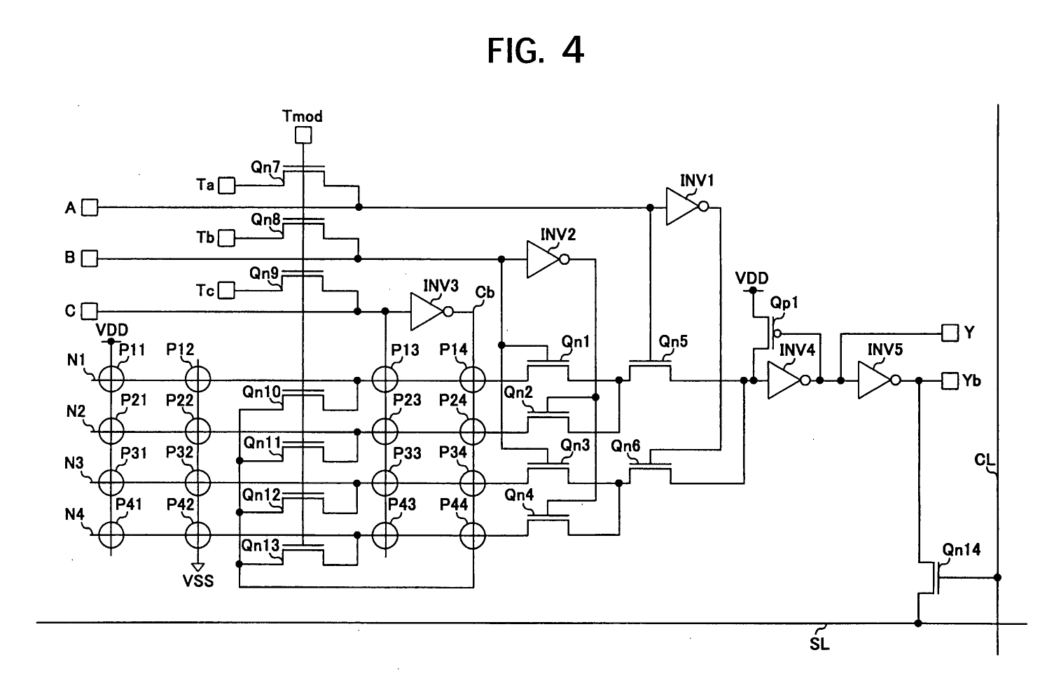

FIG. 4 is a diagram of an example of the configuration of a circuit cell of a semiconductor integrated circuit according to an embodiment having a structured ASIC configuration. The circuit cell shown in FIG. 4 has n-channel MOS type transistors Qn1 to Qn14, a p-channel MOS type transistors Qp1, and inverter circuits INV1 to INV5.

The transistors Qn1 to Qn6 and Qp1 and the inverter circuits INV1 to INV4 configure a three-input lookup table having nodes A, B, and C as inputs and having a node Y as an output.

A source of the transistor Qn1 is connected to the node N1, and its drain is connected via the transistor Qn5 to the input of the inverter circuit INV4. A source of the transistor Qn2 is connected to the node N2, and its drain is connected via the transistor Qn5 to the input of the inverter circuit INV4. A source of the transistor Qn3 is connected to the node N3, and its drain is connected via the transistor Qn6 to the input of the inverter circuit INV4. A source of the transistor Qn4 is connected to the node N4, and its drain is connected via the transistor Qn6 to the input of the inverter circuit INV4. An output of the inverter circuit INV4 is connected to the output node Y.

Gates of the transistors Qn1 and Qn3 are connected to the input node B. Gates of the transistors Qn2 and Qn4 are connected to the output of the inverter circuit INV2 for inverting the logic of the signal of the input node B. A gate of the transistor Qn5 is connected to the input node A. A gate of the transistor Qn6 is connected to the output of the inverter circuit INV1 for inverting the logic of the signal of the input node A.

The transistor Qp1 pulls up the input of the inverter circuit INV4 when the output of the inverter circuit INV4 has a low level. The source of the transistor Qp1 is connected to a power supply VDD, its drain is connected to the input of the inverter circuit INV4, and its gate is connected to the output of the inverter circuit INV4.

The inverter circuit INV3 inverts the logic of the signal of the input node C.

The logic function of the lookup table explained above is determined in accordance with the signals input to the nodes N1 to N4. Notations ‘P11’ to ‘P44’ in FIG. 4 indicate sites where vias for inputting various signals to the nodes N1 to N4 are prepared. At sites P11 to P41, vias for inputting the power supply voltage VDD as high level signals to the nodes N1 to N4 are prepared. At sites P12 to P43, vias for inputting the reference potential VSS as low level signals to the nodes N1 to N4 are prepared. At sites P13 to P44, vias for connecting the nodes N1 to N4 and the input node C are prepared. At sites P14 to P44, vias for connecting the nodes N1 to N4 and the output node Cb of the inverter circuit INV3 are prepared.

The inverter circuit INV5 inverts the logic of the output signal of the lookup table, that is, the output signal of the inverter circuit INV4, and outputs the same to the output node Yb.

The transistors Qn7 to Qn13 configure the circuit for inputting test signals to the lookup table in the operation mode for testing the circuit cells (hereinafter referred to as the “test mode”).

A drain of the transistor Qn7 is connected to an input node Ta of the test signal, and its source is connected to the input node A. A drain of the transistor Qn8 is connected to an input node Tb of the test signal, and its source is connected to the input node B. A drain of the transistor Qn9 is connected to an input node Tc of the test signal, and its source is connected to the input node C. Gates of the transistors Qn7 to Qn9 are commonly connected to a node Tmod set at a high level in the test mode.

A drain of the transistor Qn10 is connected to the node N1. A drain of the transistor Qn11 is connected to the node N2. A drain of the transistor Qn12 is connected to the node N3. A drain of the transistor Qn13 is connected to the node N4. Sources of the transistors Qn10 to Qn13 are commonly connected to the output node Cb of the inverter circuit INV3, and their gates are commonly connected to the node Tmod.

The transistor Qn14 outputs a signal indicating the test results of the lookup table to the test output line SL. A drain of the transistor Qn14 is connected to the output node Yb, its source is connected to the test output line SL, and its gate is connected to the column selection line CL. When the column selection line CL is set at a high level by the column selecting circuit 10 explained later, the transistor Qn14 becomes an ON state, and the output signal of the circuit cell output from the output node Yb is output via the transistor Qn14 to the test output line SL.

According to the circuit cell having the above configuration, the logic function thereof is determined in accordance with whether or not a via is prepared at each of the sites P11 to P44.

For example, where vias are prepared at sites P12, P21, P31, and P41, a two-input NAND circuit having nodes A and B as inputs and having the node Yb as an output is realized. Namely, when the node A is at the low level, the transistor Qn6 turns on and, at the same time, one of the transistor Qn3 or Qn4 turns on. For this reason, the input of the inverter circuit INV4 is driven by the power supply voltage VDD via the transistors Qn3 and Qn6 or the transistors Qn4 and Qn6, and the node Yb becomes the high level. When the node B is at the low level, the transistors Qn2 and Qn4 turn on and, at the same time, the transistor Qn5 or Qn6 turns on. For this reason, the input of the inverter circuit INV4 is driven by the power supply voltage VDD via the transistors Qn2 and Qn5 or the transistors Qn4 and Qn6, and the node Yb becomes the high level. When both of the nodes A and B are at the high level, the transistors Qn1 and Qn5 turn on, and the transistor Qn6 turns off, therefore the input of the inverter circuit INV4 is driven by the reference potential VSS via the transistors Qn1 and Qn5, and the node Yb becomes the low level. In this way, the output node Yb becomes the high level when one of the input node A or B is at the low level, and the output node Yb becomes the high level when both of the input nodes A and B are at the high level, therefore the circuit cell functions as a NAND circuit.

Further, in the test mode in which the node Tmod is set at the high level, all of transistors Qn7 to Qn13 turn on. Due to this, input nodes A to C of the circuit cell receive as input predetermined test signals from the test use input nodes Ta to Tc. Further, the input signals of the nodes N1 to N4 are all set at the high level or all set at the low level in accordance with the signal input from the node Tc. The logic functions of the three-input lookup table (Qn1 to Qn6, Qp1, INV1 to INV4) and the inverter circuit INV5 are checked to see if they are normal by comparing the test signals input to the input nodes Ta to Tc and the signals as the result of test output from the node Yb.

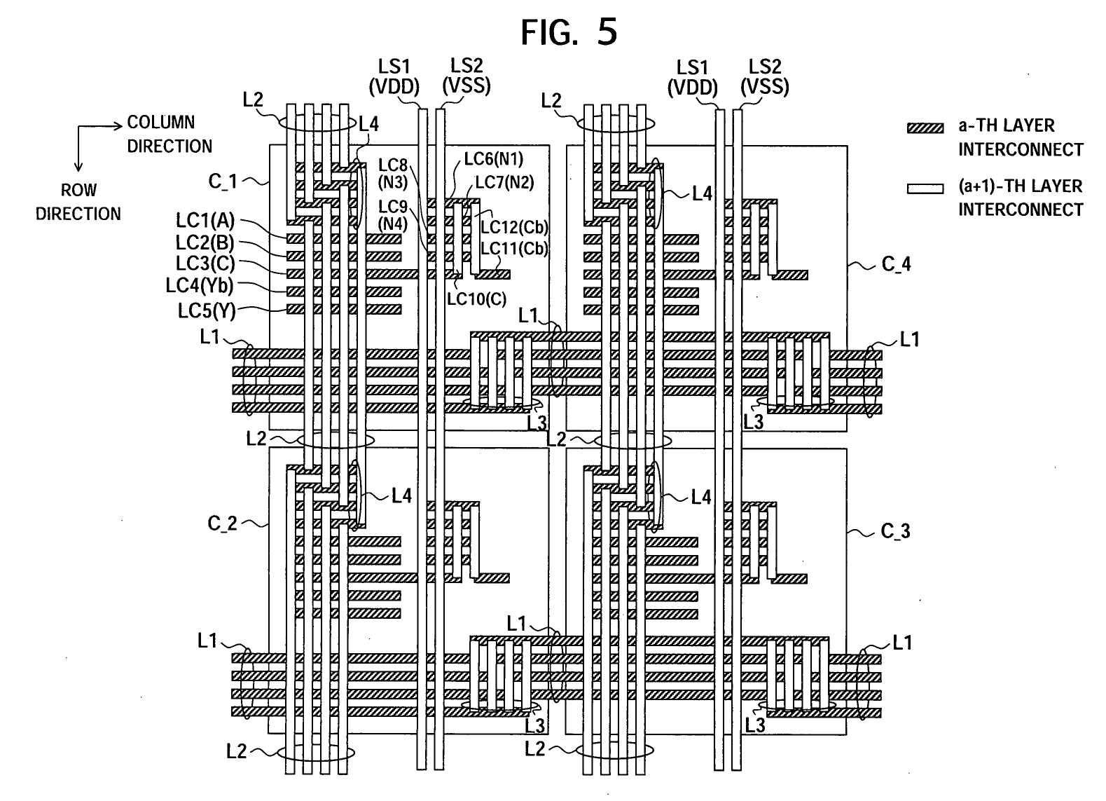

FIG. 5 is a diagram of an example of the interconnect structure of the semiconductor integrated circuit according to the present embodiment having the circuit cells shown in FIG. 4 and shows an example of interconnect patterns in an a-th layer (a indicates an integer of 1 or more) and in an upper (a+1)-th layer.

In the interconnect structure shown in FIG. 5, a group of interconnects including interconnects LC1 to LC5 is an embodiment of the first group of interconnects of the present invention. The group of interconnects including the group of interconnects L1 to L4 is an embodiment of the second group of interconnects of the present invention. Each of the interconnects LC6 to LC9 is an embodiment of the interconnect of the first node of the present invention. Each of the interconnects LS1, LS2, LC10, and LC12 is an embodiment of the interconnect of the second node of the present invention.

In the a-th layer, one group of interconnects L1 is formed for each circuit cell. The group of interconnects L1 is a bundle of four interconnects extending in the row direction and the length thereof is the same degree as the width in the row direction of the circuit cell. A plurality of groups of interconnects L1 corresponding to the circuit cells aligned in the row direction are arranged while being aligned in the row direction. The structure thereof corresponds to one obtained by obliquely cutting one group of (four) interconnects extending in the row direction for each column and arranging the cut pieces alternately offset in the column direction.

In the (a+1)-th layer, groups of interconnects L3 are formed for connecting the groups of interconnects L1 aligned in the row direction through vias. Each group of interconnects L3 is a bundle of four interconnects the same as the group of interconnects L1 and is arranged at a position crossing two adjacent groups of interconnects L1 in the upper layer.

In the (a+1)-th layer, one group of interconnects L2 is formed for each of the circuit cells. The group of interconnects L2 is a bundle of four interconnects extending in the column direction, and the length thereof is the same degree as the width of the circuit cell in the column direction. A plurality of groups of interconnects L2 corresponding to the circuit cells aligned in the column direction are arranged while being aligned in the column direction. The structure thereof corresponds to one obtained by obliquely cutting one group of (four) interconnects extending in the column direction for each row and arranging the cut pieces alternately offset in the row direction.

In the a-th layer, groups of interconnects L4 are formed for connecting the groups of interconnects L2 aligned in the column direction through vias. Each group of interconnects L4 is a bundle of four interconnects the same as the group of interconnects L2 and is arranged at a position crossing two adjacent groups of interconnects L2 in the lower layer.

In the a-th layer, interconnects LC1 to LC9 connected to input nodes (A, B, C) of circuit cells, output nodes (Y, Yb), and nodes (N1, N2, N3, N4) for programming the logic function are formed.

The interconnects LC1, LC2, LC3, LC4, and LC5 are connected to the input node A, the input node B, the input node C, the output node Y, and the output node Yb and are formed while being aligned in the column direction in this order. All of the interconnects LC1 to LC5 are formed extending to the row direction and are arranged at positions crossing the group of interconnects L2 in the upper layer.

The interconnects LC6, LC7, LC8, and LC9 are respectively connected to the programming nodes N1, N2, N3, and N4 of the logic function and are formed while being aligned in the column direction in this order. Both of the interconnects LC1 to LC1 are formed extending in the row direction and arranged at positions crossing the interconnects LS1, LS2, LC10, and LC12 in the upper layer.

The interconnect LS1 is an interconnect for supplying the power supply voltage VDD to the circuit cells of a column and is formed for each column in the (a+1)-th layer. The interconnect LS2 is an interconnect for supplying the reference potential VSS to the circuit cells of a column and is formed for each column in the (a+1)-th layer.

The interconnect LC10 is formed extending in the column direction in the (a+1)-th layer and is arranged at a position overlapping the interconnects LC6 to LC9 in the lower layer. The interconnect LC10 is an interconnect connected to the input node C and is connected to the interconnect LC3 in the lower layer through a via.

The interconnect LC12 is formed extending to the column direction in the (a+1)-th layer and is arranged at a position overlapping the interconnects LC6 to LC9 in the lower layer. The interconnect LC12 is an interconnect connected to the output node Cb of the inverter circuit INV3 and connected to the interconnect LC11 in the lower layer through a via.

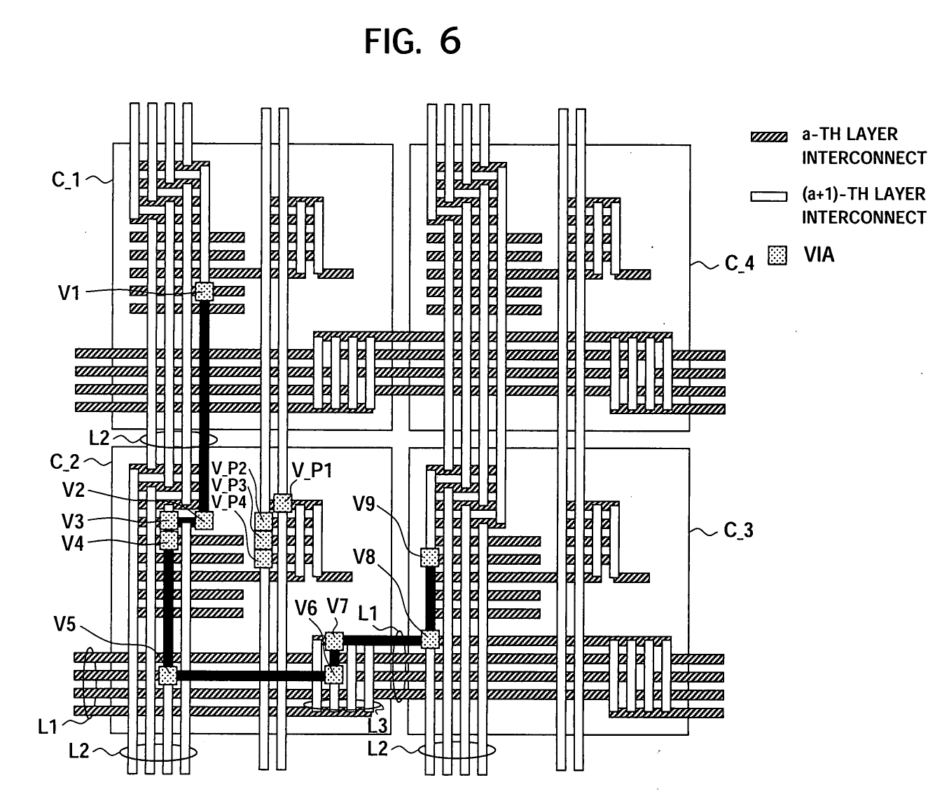

FIG. 6 is a diagram of an example of the interconnect patterns in the interconnect structure explained above. In FIG. 6, four circuit cells (C_1 to C_4) are adjacent. The circuit cells C_1 and C_2 belong to the same column, the circuit cells C_2 and C_3 belong to the same row, the circuit cells C_3 and C_4 belong to the same column, and the circuit cells C_4 and C_1 belong to the same row.

The interconnect LC4 (output node Yb) of the circuit cell C_1 is connected to the interconnect LC1 (input node A) of the circuit cell C_2 through the route of the group of interconnects L2, a via V2, the group of interconnects L4, a via V3, the group of interconnects L2, and a via V4 and, at the same time, further connected to the interconnect LC2 (input node B) of the circuit cell C_3 through the route formed by the group of interconnects L2 connected to this via V4, a via V5, the group of interconnects L1, a via V6, the group of interconnects L3, a via V7, the group of interconnects L1, a via V8, the group of interconnects L2, and a via V9. Namely, according to the example of FIG. 6, the interconnect patterns connecting the output node Yb of the circuit cell C_1 and the input node A of the circuit cell C_2 and the input node B of the circuit cell C_3 are formed by the vias V1 to V9.

Further, the interconnect LC6 (N1) of the circuit cell C_2 is connected through a via V_P1 to the interconnect LS2 (VSS), and the interconnects LC7 to LC9 (N2 to N4) are connected through vias V_P2 to V_P4 to the interconnect LS1 (VDD). Due to this, the result becomes equivalent to the case where vias are formed at sites P12, P21, P31, and P41 (FIG. 4), therefore the circuit cell C_2 shown in the example of FIG. 6 has an equivalent logic function to that of a two-input NAND circuit.

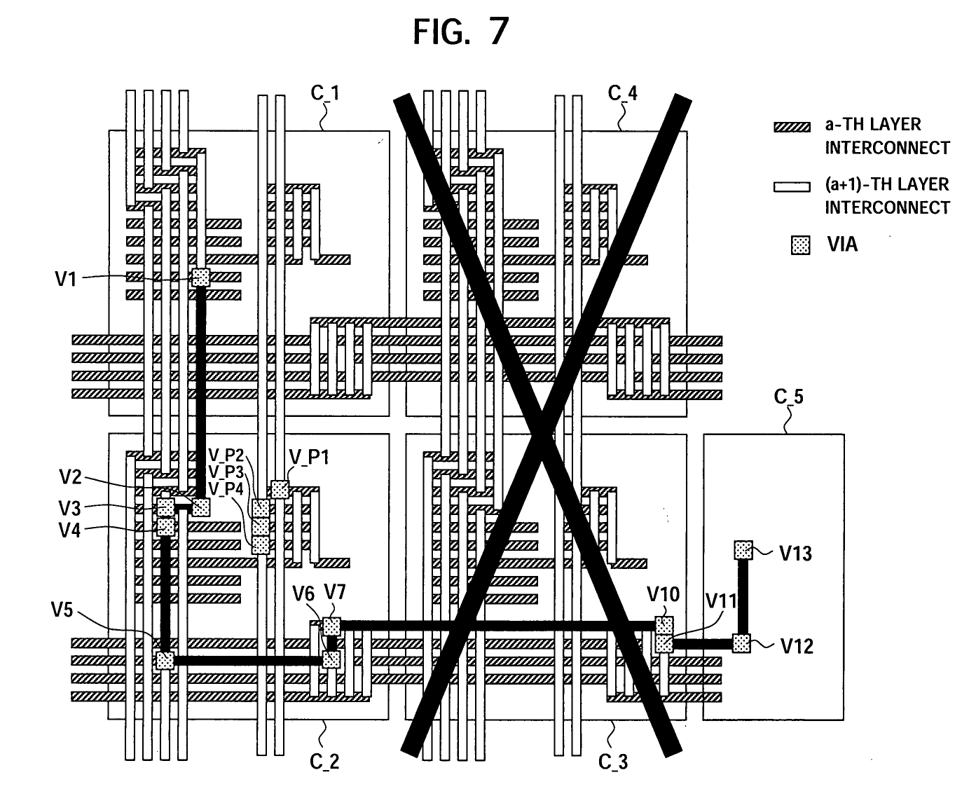

FIG. 7 is a diagram of an example of the interconnect patterns in the case where a defective cell is included in the column of circuit cells C_3 and C_4. According to this example, the function of the circuit cell C_3 which becomes unused is shifted to the circuit cell C_5 adjacent in the same row as the circuit cell C_3. Then, the interconnect spanning from the circuit cell C_2 to the circuit cell C_3 is extended to the adjacent circuit cell C_5 extended crossing the circuit cell C_3. Namely, vias V8 and V9 connecting the output node Yb of the circuit cell C_1 and the input node B of the circuit cell C_3 are deleted, and vias V10 to V13 for extending the interconnect to the input node B of the circuit cell C_5 from the input node A of the circuit cell C_2 are provided instead.

As shown in FIG. 7, the extension of the interconnect along with the repair of a defect may be about the width of one block in the row direction. For this reason, the influence of the delay due to the extension of the interconnect is very small. Further, the changed portion of an interconnect along with the repair of a defect mainly includes two portions of a portion extending the interconnect in order to by-pass the line which newly becomes unused and a portion connecting the interconnect to the line determined to be unused in the initial setup, so the change of the interconnect is very easy.

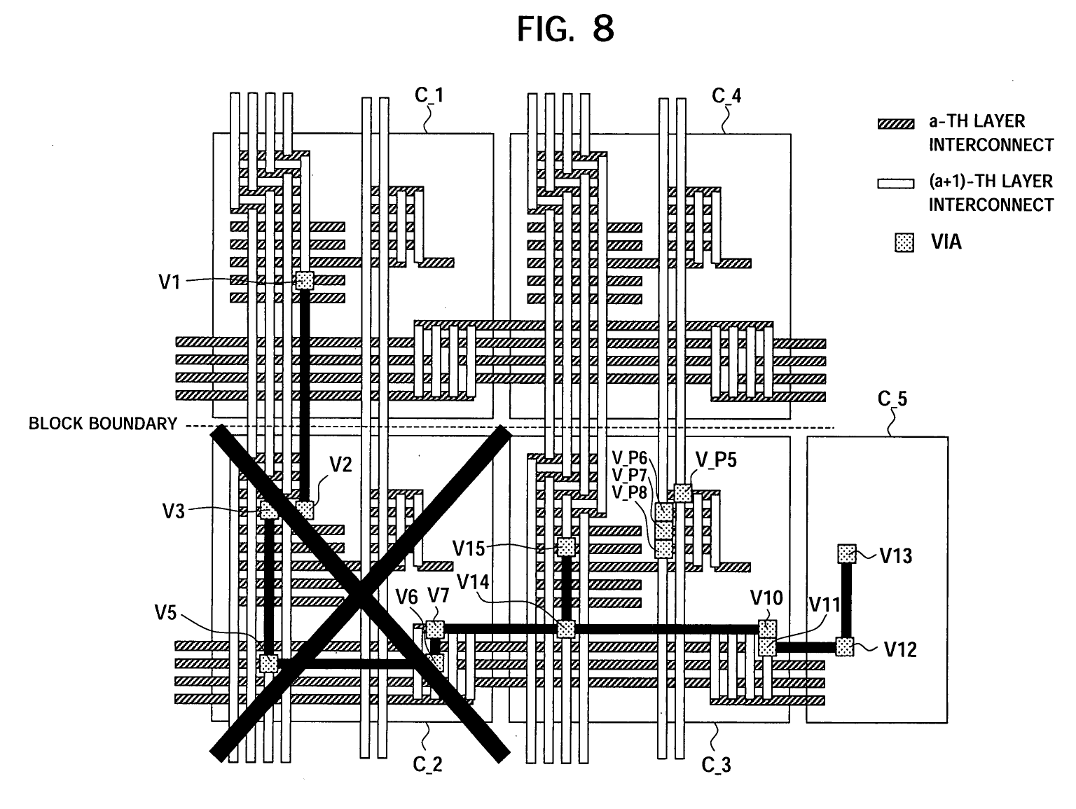

FIG. 8 is a diagram of an example where the interconnect patterns crossing a boundary of blocks is changed along with repair of a defect. The block to which the circuit cells C_1 to C_4 belong and the block to which the circuit cells C_2 and C_3 belong are different. In the state where there is no defective cell, the interconnect extends in the column direction between two circuit cells (C_1, C_2) belonging to different blocks. When the column to which the circuit cell C_2 belongs is set to be unused in this state, for example as shown in FIG. 8, the function of the circuit cell C_2 is shifted to the adjacent circuit cell C_3, and the function of the circuit cell C_3 is further shifted to the adjacent circuit cell C_5. Then, the interconnect extending from the circuit cell C_1 to the circuit cell C_2 is bent at the circuit cell C_2 and extended to the circuit cell C_3. Further, the interconnect extending from the circuit cell C_2 to the circuit cell C_3 is changed to the interconnect extending from the circuit cell C_3 to the circuit cell C_5.

In the example of FIG. 8, the via V4 connecting the output node Yb of the circuit cell C_1 and the input node A of the circuit cell C_2 and the vias V8 and V9 connecting the output node Yb of the circuit cell C_1 and the input node B of the circuit cell C_3 are deleted, and the vias V10 to V15 are formed instead. By the vias V14 and v15, the output node Yb of the circuit cell C_1 is connected to the input node A of the circuit cell C_3. Further, by the vias V13 to V13, the output node Yb of the circuit cell C_1 is connected to the input node B of the circuit cell C_5.

When an interconnect crossing different blocks is extended to the row direction, even if switching with unused columns occurs due to the repair of a defect, the entire interconnect patterns shift parallel to the direction in which the interconnect extends, therefore only the length of the interconnect is extended or shortened, so the change of the interconnect patterns is very small. Namely, when the interconnect extends crossing blocks to a direction (row direction) different from the direction in which the unused circuit cells are aligned (column direction), the change of the interconnect patterns along with the repair of a defect can be kept very small. Contrary to this, if an interconnect crossing blocks extends to the column direction, if switching of unused columns occurs due to repair of a defect, the entire interconnect patterns shift vertically in the direction to which the interconnect extends, therefore there arises a necessity of bending the interconnect for example as shown in FIG. 8. Namely, when the interconnect extends crossing blocks in the same direction (column direction) as the direction in which the unused circuit cells are aligned (column direction), it is necessary to bend the interconnect patterns along with the repair of the defect, and the change of the interconnect becomes slightly complex. For this reason, the interconnects crossing blocks in the semiconductor integrated circuit according to the present embodiment are preferably arranged in the row direction (direction different from the direction in which the unused circuit cells are aligned) as much as possible. Such interconnects can be easily achieved by designing the device so that circuits are configured in units of blocks.

Further, in the case where there is an interconnect crossing blocks in the column direction, in order to make the change of the interconnect along with repair of a defect smaller, for example at least one circuit cell adjacent to the circuit cell at the boundary of blocks through which this interconnect passes in the row direction (that is, a direction different from the direction in which the unused circuit cells are aligned) may be previously set as an unused circuit cell. Due to this, where the interconnect is shifted to the row direction along with repair of a defect, the interconnect can be bent to the row direction by using the interconnect provided for these unused cells, therefore the change of the interconnect can be simplified.

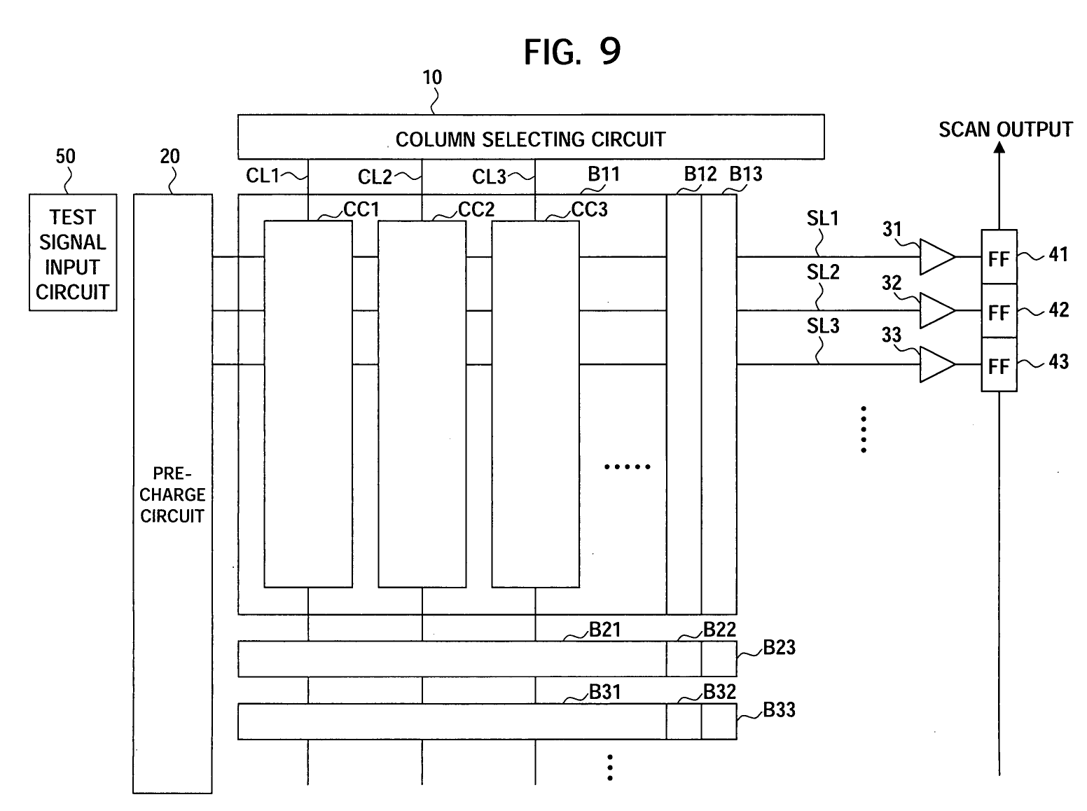

Next, an explanation will be given of the method of test of circuit cells in a semiconductor integrated circuit according to the present embodiment. FIG. 9 is a diagram of an example of circuits involved in test of circuit cells. The same notations shown in FIG. 1 and FIG. 9 indicate the same components.

The semiconductor integrated circuit according to the present embodiment has, as circuits for test of circuit cells, a column selecting circuit 10, a precharge circuit 20, sense amplifiers 31, 32, 33, . . . , scan flip-flops 41, 42, 43, . . . , and a test signal input circuit 50.

The column selecting circuit 10, in the test mode for testing a circuit, successively sets the column selection lines CL1, CL2, CL3, . . . at the high level. Note that the column selection lines CL1, CL2, CL3, . . . are commonly connected to the circuit cells of the first column, second column, third column, . . . . When for example the i-th column selection line CLi is set at the high level by the column selecting circuit 10, in the circuit cells connected to this column selection line CLi, the transistors Qn14 turn on. As a result, signals indicating test results of circuit cells in the i-th column are output to the test output lines SL1, SL2, SL3, . . . .

The precharge circuit 20 precharges the test output lines SL1, SL2, SL3, . . . to the power supply voltage VDD before the column selection line is set at the high level in the column selecting circuit 10. Note, the test output lines SL1, SL2, SL3, . . . are commonly connected to the circuit cells of the first row, second row, third row, . . . .

The sense amplifiers 31, 32, 33, . . . amplify signals of test results of circuit cells output to the test output lines SL1, SL2, SL3, . . . .

The scan flip-flops 41, 42, 43, . . . latch the signals of the test results amplified at the sense amplifiers 31, 32, 33, . . . and output the same as serial data.

The test signal input circuit 50, in the test mode for testing circuit cells, inputs the test signals to circuit cells in the semiconductor integrated circuit. For example, it generates test signals of a plurality of patterns and successively inputs them to the circuit cells.

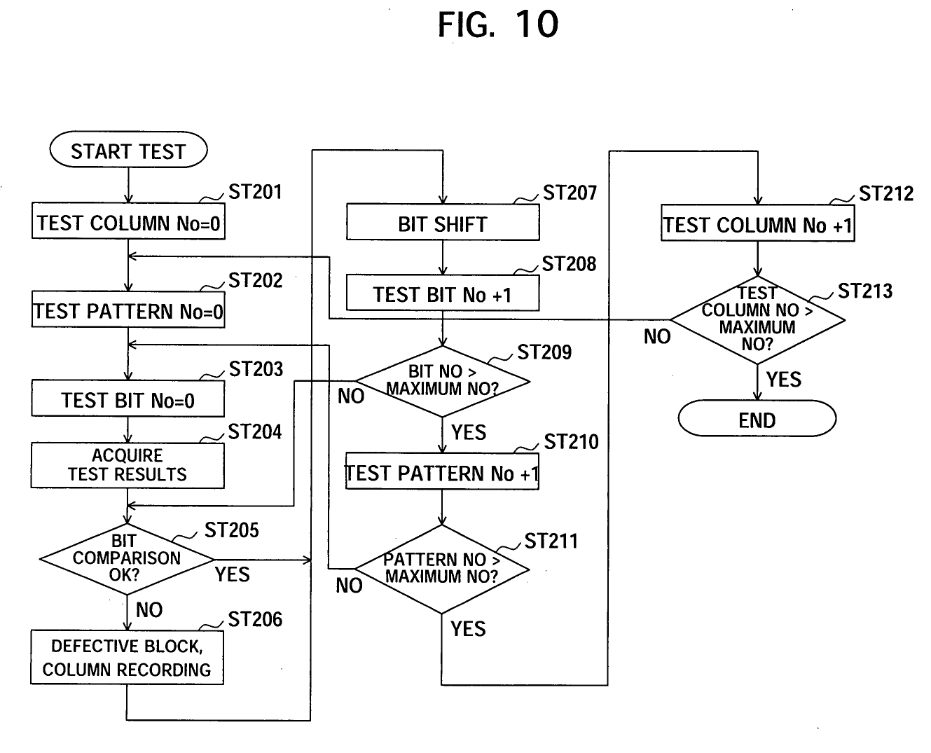

FIG. 10 is a flow chart illustrating an example of the test processing by the circuit shown in FIG. 9.

First, at the time of the start of the test, numbers indicating columns to be tested (hereinafter referred to as “test column numbers”), numbers indicating patterns of test signals (hereinafter referred to as “test pattern numbers”), and numbers indicating rows to be tested (hereinafter referred to as “test bit numbers”) are initialized to ‘0’ (steps ST201 to ST203).

Then, test signals indicated by test pattern numbers are input from the test signal input circuit 50 to the circuit cells, and the column selection line of the column indicated by the test column number is activated by the column selecting circuit 10. Due to this, signals of test results output from circuit cells of this column are amplified at sense amplifiers 31, 32, 33, . . . and latched at the scan flip-flops 41, 42, 43, . . . (step ST204).

Then, among these latched data, the data of the row indicated by the test bit number is compared with the expected value (step ST205). When it is different from the expected value, the information of the block and column of the defective cell outputting this data are recorded (step ST206). When it coincides with the expected value, the data of the scan flip-flops 41, 42, 43, . . . are shifted by 1 bit (step ST207), and ‘1’ is added to the test bit number (step ST208). At this time, when the test bit number does not reach the predetermined maximum value (that is, the number indicating the last row), and the processing of steps ST204 to ST208 explained above is repeated for the data of the next row corresponding to the test bit number incremented by ‘1’.

When it is judged that the test bit number reaches the predetermined maximum value (that is, the number indicating the last row) (step ST209), ‘1’ is added to the test pattern number (step ST210). At this time, when the test pattern number does not reach the predetermined maximum value (that is, the number indicating the last pattern), the test signal of the next pattern corresponding to the test pattern number incremented by ‘1’ is input to each circuit cell from the test signal input circuit 50, and the processing of steps ST203 to ST210 explained above is repeated.

When it is judged that the test pattern number reaches the predetermined maximum value (that is, the number indicating the last pattern) (step ST211), ‘1’ is added to the test column number. At this time, when the test column number does not reach the predetermined maximum value (that is, the number indicating the last column), the column selection signal of the next column corresponding to the test column number incremented by ‘1’ is set at the high level by the column selecting circuit 10, and the processing of steps ST202 to ST212 explained above is repeated. When it is judged that the test column number reaches the predetermined maximum number (that is, the number indicating the last column) (step ST213), the test of all circuit cells ends.

Next, an explanation will be given of the method of control of the power supply of the circuit cells in a semiconductor integrated circuit according to the present embodiment.

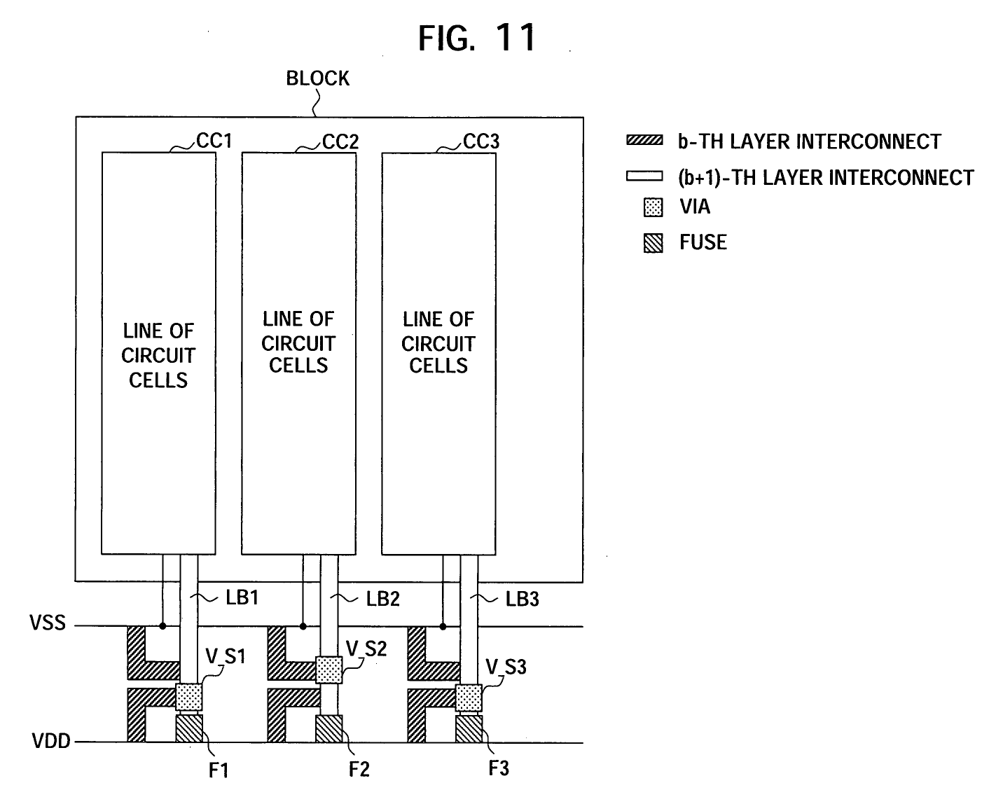

FIG. 11 is a diagram showing an example of the circuit for controlling the power supply to the circuit cells in the semiconductor integrated circuit according to the present embodiment. The circuit cell columns CC1, CC2, CC3, . . . in the block are connected via fuses F1, F2, F3, . . . to the branch lines LB1, LB2, LB3, . . . , and the power supply voltage VDD is supplied via each branch line. The fuses F1, F2, F3, . . . are formed so that all become ON in the stage before testing the circuit cells explained above, and all are disconnected when the circuit test ends. Vias are formed between the supply line of the reference potential VSS or the supply line of the power supply voltage VDD and the branch lines so that when it is judged that all circuit cells are normal, the reference potential VSS is supplied to the branch line of the circuit cell column previously set to be unused, and the power supply voltage VDD is supplied to the other branch line. On the other hand, vias are formed between the supply line of the reference potential VSS or the supply line of the power supply voltage VDD and the branch lines so that when a defective cell is detected by the test, the reference potential VSS is supplied to the branch line of the column including this defective cell, and the power supply voltage VDD is supplied to the branch line of the other used circuit cell column. For example, in the example of FIG. 11, the defective cell is detected in the circuit cell column CC2, therefore the branch line LB2 connected to this column is connected through the via V_S2 to the reference potential VSS.

In this way, by the semiconductor integrated circuit according to the present embodiment, in each block, the control of whether or not the power is supplied is carried out for each column of circuit cells aligned in the same direction as the direction in which the unused circuit cells are aligned (that is, aligned in the column direction). Then, at least the power supply to the column of circuit cells set to be unused due to the repair of a defect is cut off. Due to this, the supply of power with respect to the column including the defective cell is cut off and the occurrence of the wasteful power loss due to leaked current etc. can be prevented.

If repairing defects of circuit cells not in units of columns, but for individual circuit cells, it becomes necessary to also cut off the supply of the power to the defective cell for each circuit cell, therefore the numbers of elements of the circuit cells becomes larger, and the scale of the semiconductor integrated circuit greatly increases. Contrary to this, according the semiconductor integrated circuit of the present embodiment, the repair of defects and the control of the power supply are carried out in units of columns, therefore the number of elements of the circuits involved in power supply control can be kept very small.

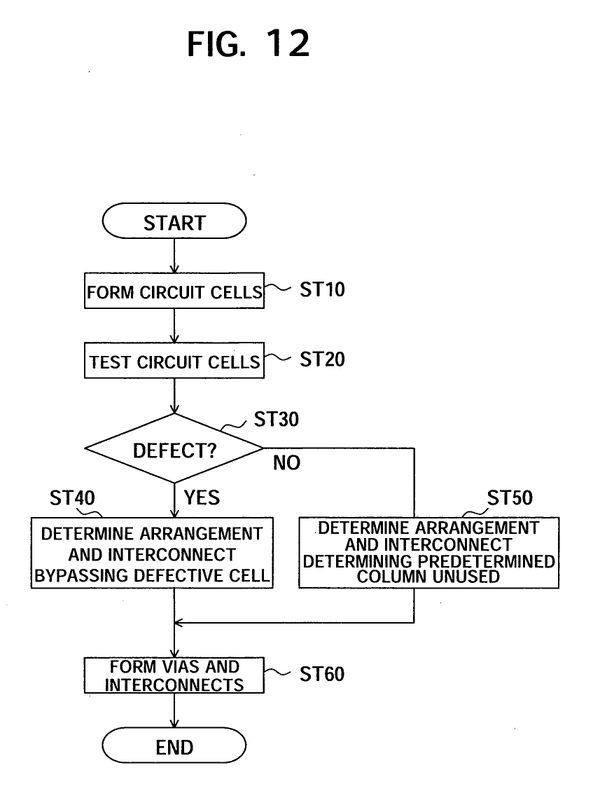

Next, an explanation will be given of the method of producing a semiconductor integrated circuit according to the present embodiment by referring to the flow chart shown in FIG. 12.

Step ST10

First, circuit cells shown in FIG. 1 to FIG. 4, FIG. 9, and FIG. 11, the circuit for testing the circuit cells, the circuit for controlling the power supply, etc. are formed on a semiconductor substrate. Note that the groups of interconnects in the (a+1)-th layer which may be changed in interconnect patterns in the following step and the vias between the a-th layer and the (a+1)-th layer have not yet been formed in this step. Further, in this step, the circuit for controlling the power supply shown in FIG. 11 is formed so that the power supply is supplied to the circuit cells of all columns.

Step ST20

Then, the circuit cells formed at step ST10 are tested. This test is carried out by for example the routine shown in the flow chart of FIG. 11.

Step ST30

It is judged whether or not a defective cell is found in the test results of step ST20.

Step ST40

When a defective cell is found in a certain block in the test of step ST20, the column of circuit cells including the defective cell is set as an unused column in place of a column of circuit cells previously set as unused in this block. Note that when a plurality of columns of circuit cells are previously set as unused columns in the block and a plurality of defective cells are found within a range not exceeding this, the columns of circuit cells including the found defective cells are set as unused columns in place of part or all of the plurality of columns of circuit cells set as unused columns. When the unused columns of circuit cells are changed in this way, for at least a part of the remainder of circuit cells in a block other than these unused columns of circuit cells, the processing for determining the interconnect route and the logic function is carried out. As previously explained, the change of the interconnect patterns and the change of arrangement of circuit cells due to the shift of unused columns of circuit cells to the row direction are very small, therefore this processing can be executed at a high speed.

Step ST50

When no defective cell is found in any block in the test of step ST20, the processing for determining the interconnect route and the logic function is carried out for at least a part of the remainder of circuit cells other than one or more columns of circuit cells previously set to be unused. Note that when the interconnect route and the logic function in this case have been already designed, the next step ST60 is executed by using this design data.

Step ST60

The formation of the interconnects of circuit cells and the programming of the logic function are carried out based on the interconnect route and the logic function determined at step ST40 or step ST50. For example, in the case of the interconnect structure as shown in FIG. 5, by forming the vias between the a-th layer and the (a+1)-th layer and forming the groups of interconnects in the (a+1)-th layer above that, the formation of the interconnects of the circuit cells and the programming of the logic function can be simultaneously carried out. In this case, when using the technique of drawing the resist patterns of the vias using for example an electron beam, different via patterns can be formed for each semiconductor chip.

Further, at step ST60, the circuit for controlling the power supply shown in FIG. 11 is formed so that the supply of power to the column in which the defective cell was found at step ST20 is cut off. Namely, vias VS_1, VS_2, VS_3, . . . are formed between the branch lines LB1, LB2, and LB3 and the power supply voltage VDD or the reference potential VSS so that the supply of the power to at least the column in which the defective cell was found is cut off after all of the fuses F1, F2, F3, . . . are disconnected.

An embodiment of the present invention was explained in detail above, but the present invention is not limited to only the above embodiment and includes various variations.

The unused lines of circuit cells may be arranged in any columns in the block, but the amount of change of the interconnect patterns along with the repair of a defect can be kept small by arranging lines at constant intervals in the block. Further, by previously arranging an unused line of circuit cells at one end in the block, the interconnect patterns can be always shifted to a constant direction irrespective of the position of the defective cell.

The number of circuit cells configuring the block and the alignment thereof may be all the same or may be different in at least a part of the block.

In the example of FIG. 11, the example of controlling the supply of the power in units of columns by using fuses was shown, but the present invention is not limited to this. Control may be carried out by using for example switches etc. as well.

It should be understood by those skilled in the art that various modifications, combinations, sub-combinations and alterations may occur depending on design requirements and other factors insofar as they are within the scope of the appended claims or the equivalents thereof.

What we claim is:

1. A semiconductor integrated circuit comprising:
a plurality of circuit cells aligned in a row direction and a column direction in a matrix form and including at least one line of unused ciruit cells aligned in the row direction or the column direction and a plurality of usable circuit cells, and
at least one group of interconnects connecting at least a part of the pulurality of usable circuit cells.

2. A semiconductor integrated circuit as set forth in claim 1, wherein the line of unused circuit cells include a defective circuit cell.

3. A semiconductor integrated circuit as set forth in claim 1, wherein
the plurality of circuit cells are divided into a plurality of blocks each including one or more lines of unused circuit cells aligned in the row direction or the column direction, and
the groups of interconnects connect at least a part of the plurality of usable circuit cells in each of the blocks.

4. A semiconductor integrated circuit as set forth in claim 3, wherein the line of unused circuit cells include a defective circuit cell.

5. A semiconductor integrated circuit as set forth in claim 3, wherein the groups of interconnects include:
a first group of interconnects including an input interconnect and an output interconnect of each circuit cell,
a second group of interconnects, and
a third group of interconnects including an interconnect selectively connecting an interconnect included in the first group of interconnects and an interconnect included in the second group of interconnects and an interconnect selectively connecting interconnects included in the second group of interconnects to each other.

6. A semiconductor integrated circuit as set forth in claim 5, wherein:
the first group of interconnects is formed in a first interconnect layer,
the second group of interconnects is formed in a second interconnect layer covering the first interconnect layer, and
the third group of interconnects includes a via selectively connecting an interconnect formed in the first interconnect layer and an interconnect formed in the second interconnect layer.

7. A semiconductor integrated circuit as set forth in claim 6, wherein the second group of interconnects includes:
a group of interconnects extending in the row direction and formed in the first interconnect layer,
a group of interconnects extending in the column direction and formed in the second interconnect layer,
a group of interconnects connecting the interconnects extending in the row direction to each other through the via and formed in the second interconnect layer, and
a group of interconnects connecting the interconnects extending in the column direction to each other through the via and formed in the first interconnect layer.

8. A semiconductor integrated circuit as set forth in claim 3, wherein the plurality of circuit cells can be programmed in logic functions.

9. A semiconductor integrated circuit as set forth in claim 8, wherein each circuit cell includes:
one or more first nodes,
one or more second nodes, and
interconnects selectively connecting the first node and the second node and
each circuit cell has a logic function in accordance with the state of connection of the first nodes and the second nodes.

10. A semiconductor integrated circuit as set forth in claim 6, wherein each circuit cell includes:
one or more first nodes connected to an interconnect formed in the first interconnect layer,
one or more second nodes connected to an interconnect formed in the second interconnect layer, and
one or more vias selectively connecting the first nodes and the second nodes, and
each circuit cell has a logic function in accordance with the state of connection of the first nodes and the second nodes.

11. A semiconductor integrated circuit as set forth in claim 3 further comprising a power supply control circuit for controlling whether or not the power is supplied for each line of circuit cells aligned in the same direction as the direction in which the unused circuit cells are aligned and at least cutting off the supply of the power to the unused circuit cells.

12. A semiconductor integrated circuit as set forth in claim 11, wherein
the semiconductor integrated circuit comprises:
at least one power supply line and
a plurality of branch lines branching from said power supply line to said blocks and supplying power to each line of circuit cells aligned in the same direction as the direction of alignment of unused circuit cells in the blocks and
the power supply control circuit includes a plurality of fuse circuits inserted between said power supply line and plurality of branch lines.

13. A semiconductor integrated circuit as set forth in claim 3, wherein
the semiconductor integrated circuit comprises:
a plurality of test output lines connected to circuit cells in the same row,
a plurality of column selection lines connected to circuit cells in the same column,
a column selecting circuit for successively activating the plurality of column selection lines in an operation mode for testing the circuit cells, and
a test signal input circuit for inputting test signals to the plurality of circuit cells in the operation mode for testing the circuit cells and
each circuit cell generates a signal in accordance with an input test signal when the connected column selection line is activated in the operation mode for testing the circuit cell and outputs the generated signal to the connected test output line.

14. A method of producing a semiconductor integrated circuit comprising:
a first step of forming a plurality of circuit cells aligned in a row direction and a column direction in a matrix form,
a second step of testing each of the plurality of circuit cells,
a third step of determining a first interconnect route, when all of the plurality of circuit cells are judged to be normal in the second step, so that one or more lines of predetermined circuit cells aligned in the row direction or the column direction among the plurality of circuit cells are unused and at least a part of the plurarity of circuit cells other than the unused circuit cells are in use,
a fourth step of determining a second interconnect route, when a defective circuit cell is found among the plurality of circuit cells in the test of the second step, so that the line of circuit cells including the defective circuit cell and aligning in the same direction as the direction in which the predetermined circuit cells are aligned are unused in place of at least part of the lines of the predetermined circuit cells and at least a part of the plurarity of the circuit cells other than the unused circuit cells are in use, and
a fifth step of forming a group of interconnects connecting at least a part of the plurarity of circuit cells other than the unused circuit cells based on the first interconnect route or the second interconnect route.

15. A method of producing a semiconductor integrated circuit as set forth in claim 14, further comprising
testing each of the divided blocks of said plurality of circuit cells in the second step,
determining the first interconnect route for a block judged to be normal by the second step in the third step, and
determining the second interconnect route for a block judged to include a defective circuit cell by the second step in the forth step.

16. A method of producing a semiconductor integrated circuit as set forth in claim 15, further comprising:
forming circuit cells able to be programmed in logic function in the first step,
determining the logic functions of at least part of the plurarity of circuit cells other than the unused circuit cells in the third step and the forth step, and
programming the logic functions of at least part of the plurarity of circuit cells other than the unused circuit cells based on the determined logic functions in the fifth step.

17. A method of producing a semiconductor integrated circuit as set forth in claim 15, wherein,
in the first step, a power supply control circuit for controlling whether or not power is supplied for each line of circuit cells aligned in the same direction as the direction in which the unused circuit cells are aligned in each of the blocks and supplying power to all lines of circuit cells is formed and,
in the fifth step, the power supply control circuit is programmed so that the supply of the power to at least the line in which the defective circuit cell is found in the second step is cut off.
